(19) United States
(12) Patent Application Publication
(10) Pub. No.: US 2008/0047602 A1
(43) Pub. Date: Feb. 28, 2008

(54) Front contact with high-function TCO for use in photovoltaic device and method of making same

(75) Inventor: Alexey Krasnov, Canton, MI (US)

Correspondence Address: NIXON & VANDERHYE, PC, 901 NORTH GLEBE ROAD, 11TH FLOOR, ARLINGTON, VA, 22203, US

(73) Assignee: Guardian Industries Corp., Auburn Hills, MI (US)

(21) Appl. No.: 11/507,660

(22) Filed: Aug. 22, 2006

(51) Int. Cl. H01L 31/00

(52) U.S. Cl. 136/256

(57) ABSTRACT

This invention relates to a front contact for use in an electronic device such as a photovoltaic device. In certain example embodiments, the front contact of the photovoltaic device includes a low work-function transparent conductive oxide (TCO) of a material such as tin oxide, zinc oxide, or the like, and a thin high work-function TCO of a material such as oxygen-rich ITO (indium tin oxide) or the like. The high-work function TCO is located between the low work-function TCO and the uppermost semiconductor layer of the photovoltaic device so as to provide for substantial work-function matching between the low work-function TCO and the high work-function uppermost semiconductor layer of the device in order to reduce a potential barrier for holes extracted from the device by the front contact.

This invention relates to a photovoltaic device including a front contact. In certain example embodiments, the front contact of the photovoltaic device includes a low work-function transparent conductive oxide (TCO) of a material such as tin oxide, zinc oxide, or the like, and a thin high work-function TCO of a material such as oxygen-rich ITO (indium tin oxide) or the like. The high-work function TCO is located between the low work-function TCO and the uppermost semiconductor layer of the photovoltaic device so as to provide for substantial work-function matching between the low work-function TCO and the high work-function uppermost semiconductor layer of the device in order to reduce a potential barrier for holes extracted from the device by the front contact.

### BACKGROUND AND SUMMARY OF EXAMPLE EMBODIMENTS OF INVENTION

Photovoltaic devices are known in the art (e.g., see U.S. Pat. Nos. 6,784,361, 6,288,325, 6,613,603, and 6,123,824, the disclosures of which are hereby incorporated herein by reference). Amorphous silicon photovoltaic devices, for example, include a front contact or electrode. Typically, the transparent front contact is made of a transparent conductive oxide (TCO) such as zinc oxide or tin oxide formed on a substrate such as a glass substrate. In many instances, the transparent front contact is formed of a single layer using a method of chemical pyrolysis where precursors are sprayed onto the glass substrate at approximately 400 to 600 degrees C.

Typical TCOs used for certain front contacts of photovoltaic devices are n-type and therefore can create a Schottky barrier at the interface between the TCO and the uppermost semiconductor layer of the photovoltaic device (e.g., p-type silicon based layer) in a reverse direction to the built-in field. This barrier can act as a barrier for holes extracted from the device by the front contact, thereby leading to inefficient performance.

Thus, it will be appreciated that there exists a need in the art for an improved front contact for a photovoltaic device which can reduce the potential barrier for holes extracted from the photovoltaic device by the front contact.

In order to overcome the aforesaid problem, the front contact of the photovoltaic device is provided with both (a) a low work-function TCO of a material such as tin oxide, zinc oxide, or the like, and (b) a high work-function TCO of a material such as a thin layer of oxygen-rich ITO or the like. The high-work function TCO is located between the low work-function TCO and the uppermost semiconductor layer of the photovoltaic device so as to provide for substantial work-function matching between the low work-function TCO and the high work-function uppermost semiconductor layer of the device, so as to reduce a potential barrier for holes extracted from the device by the front contact.

In certain example embodiments of this invention, there is provided a photovoltaic device comprising: a front glass substrate; an active semiconductor film; an electrically conductive and substantially transparent front contact located between at least the front glass substrate and the semiconductor film; wherein the front contact comprises (a) a first transparent conductive oxide (TCO) film having a relatively low work-function and (b) a second TCO film having a relatively high work-function; and wherein the second TCO film having the relatively high work-function which is higher than the work-function of the first TCO film being located between and contacting the first TCO film and an uppermost portion of the semiconductor film.

In other example embodiments of this invention, there is provided a front contact adapted for use in a photovoltaic device including an active semiconductor film, the front contact comprising: a front glass substrate; a first substantially transparent conductive oxide (TCO) film; a second substantially transparent conductive oxide (TCO) film having a high work-function, wherein the work-function of the second TCO film is higher than that of the first TCO film; and wherein the first TCO film is located between the glass substrate and the second TCO film, so that the second TCO film having the high work-function is adapted to be located between and contacting the first TCO film and an uppermost portion of the semiconductor film of the photovoltaic device.

In still further example embodiments of this invention, there is provided a method of making a photovoltaic device, the method comprising: providing a glass substrate; depositing a first substantially transparent conductive oxide (TCO) film on the glass substrate; depositing a second substantially transparent conductive oxide (TCO) film having a relatively high work-function on the glass substrate over and contacting the first TCO film, wherein the second TCO film has a higher work-function than does the first TCO film; and forming the photovoltaic device so that the second TCO film having the relatively high work-function is sandwiched between and contacts each of the first TCO film and a semiconductor film of the photovoltaic device.

### BRIEF DESCRIPTION OF THE DRAWINGS

FIG. 1 is a cross sectional view of an example photovoltaic device according to an example embodiment of this invention.

FIG. 2 is a graph illustrating band and Fermi level positions of certain TCO materials and a p-type a-Si:H with respect to a vacuum level and a normal hydrogen electrode (NHE).

FIGS. 3(a)-3(g) are graphs illustrating the relative positions of separated TCO layers and a-Si:H layers.

### DETAILED DESCRIPTION OF EXAMPLE EMBODIMENTS OF THE INVENTION

Photovoltaic devices such as solar cells convert solar radiation and other light into usable electrical energy. The energy conversion occurs typically as the result of the photovoltaic effect. Solar radiation (e.g., sunlight) impinging on a photovoltaic device and absorbed by an active region of semiconductor material (e.g., a semiconductor film including one or more semiconductor layers such as a-Si layers) generates electron-hole pairs in the active region. The electrons and holes may be separated by an electric field of a junction in the photovoltaic device. The separation of the electrons and holes by the junction results in the generation of an electric current and voltage. In certain example embodiments, the electrons flow toward the region of the semiconductor material having n-type conductivity, and holes flow toward the region of the semiconductor having p-type conductivity. Current can flow through an external circuit connecting the n-type region to the p-type region as light continues to generate electron-hole pairs in the photovoltaic device.

In certain example embodiments, single junction amorphous silicon (a-Si) photovoltaic devices include three semiconductor layers. In particular, a p-layer, an n-layer and an i-layer which is intrinsic. The amorphous silicon film (which may include one or more layers such as p, n and i type layers) may be of hydrogenated amorphous silicon in certain instances, but may also be of or include hydrogenated amorphous silicon carbon or hydrogenated amorphous silicon germanium, or the like, in certain example embodiments of this invention. For example and without limitation, when a photon of light is absorbed in the i-layer it gives rise to a unit of electrical current (an electron-hole pair). The p and n-layers, which contain charged dopant ions, set up an electric field across the i-layer which draws the electric charge out of the i-layer and sends it to an optional external circuit where it can provide power for electrical components. It is noted that while certain example embodiments of this invention are directed toward amorphous-silicon based photovoltaic devices, this invention is not so limited and may be used in conjunction with other types of photovoltaic devices in certain instances including but not limited to devices including other types of semiconductor material, tandem thin-film solar cells, and the like.

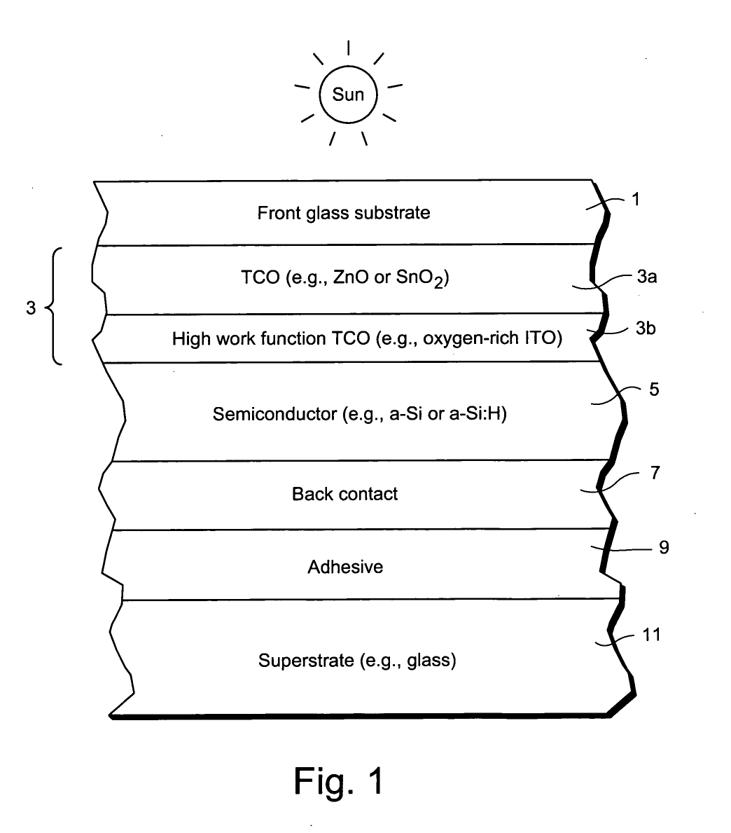

FIG. 1 is a cross sectional view of a photovoltaic device according to an example embodiment of this invention. The photovoltaic device includes transparent front glass substrate 1, front electrode or contact 3 which is of or includes both (a) a low work-function TCO 3a such as tin oxide, fluorine-doped tin oxide, zinc oxide, aluminum-doped zinc oxide, indium zinc oxide, or the like, and (b) a high work-function TCO 3b of or including a material such as oxygen-rich ITO or the like, active semiconductor film 5 of one or more semiconductor layers, back electrode or contact 7 which may be of a TCO or a metal, an optional encapsulant 9 or adhesive of a material such as ethyl vinyl acetate (EVA) or the like, and an optional superstrate 11 of a material such as glass. Of course, other layer(s) which are not shown may also be provided in the device. Front glass substrate 1 and/or rear superstrate (substrate) 11 may be made of soda-lime-silica based glass in certain example embodiments of this invention. While substrates 1, 11 may be of glass in certain example embodiments of this invention, other materials such as quartz or the like may instead be used. Moreover, superstrate 11 is optional in certain instances. Glass 1 and/or 11 may or may not be thermally tempered and/or patterned in certain example embodiments of this invention. Additionally, it will be appreciated that the word “on” as used herein covers both a layer being directly on and indirectly on something, with other layers possibly being located therebetween.

In certain example embodiments of this invention, the photovoltaic device may be made by providing glass substrate 1, and then depositing (e.g., via sputtering or any other suitable technique) TCO 3a on the substrate 1. Then, the high work-function TCO 3b is deposited on the substrate 1 over and contacting the TCO 3a. Thereafter the structure including substrate and front contact 3 is coupled with the rest of the device in order to form the photovoltaic device shown in FIG. 1. For example, the semiconductor layer 5 may then be formed over the front contact structure on substrate 1, or alternatively may be formed on the other substrate with the front contact structure thereafter being coupled to the same. Front contact layers 3a and 3b are typically continuously, or substantially continuously, provided over substantially the entire surface of the semiconductor film 5 in certain example embodiments of this invention.

In certain example embodiments of this invention, the front contact 3 of the photovoltaic device is provide with both a low work-function TCO 3a (e.g., n-type) of a material such as tin oxide, zinc oxide, or the like, and a thin high work-function TCO 3b of a material such as a thin layer of oxygen-rich ITO or the like. The high-work function TCO 3b is located between the low work-function TCO 3a and the uppermost semiconductor portion (e.g., p-type semiconductor portion) of film 5 of the photovoltaic device so as to provide for substantial work-function matching between the low work-function TCO 3a and the high work-function uppermost semiconductor portion of the device, so as to reduce a potential barrier for holes extracted from the device by the front contact. In certain example embodiments of this invention, layer 3b may be formed by sputtering a ceramic ITO target in a gaseous atmosphere including a mixture of Ar (and/or any other inert gas) and oxygen gases. In other example embodiments, layer 3b may be formed by sputtering a metal InSn target in a gaseous atmosphere including a mixture of Ar (and/or any other inert gas) and oxygen gases, with a high amount of oxygen gas being used to cause the ITO layer 3b to be oxygen rich and thus have a high work function.

In certain example embodiments of this invention, the high work-function layer 3b has a work-function of from about 4.5 to 5.7 eV, more preferably from about 4.5-5.3 eV, even more preferably from about 4.7-5.3 eV, and possibly from about 4.9-5.3 eV. In certain example embodiments of this invention, the high work-function layer 3b has a thickness of from about 10-300 Å, more preferably from about 10-100 Å. In certain example embodiments of this invention, the work function of layer 3b is higher than that of TCO layer 3a, and is lower or comparable to that of the uppermost portion (e.g., p-type a-Si:H) of the semiconductor film 5.

In certain example embodiments of this invention, the overall front contact 3, including both TCO layers 3a and 3b, may have a sheet resistance (Rₛ) of from about 7-50 ohms/square, more preferably from about 10-25 ohms/square, and most preferably from about 10-15 ohms/square using a reference example non-limiting overall thickness of from about 1,000 to 2,000 angstroms.

The active semiconductor region or film 5 may include one or more layers, and may be of any suitable material. For example, the active semiconductor film 5 of one type of single junction amorphous silicon (a-Si) photovoltaic device includes three semiconductor layers, namely a p-layer, an n-layer and an i-layer. The p-type a-Si layer of the semiconductor film 5 may be the uppermost portion of the semiconductor film 5 in certain example embodiments of this invention; and the i-layer is typically located between the p and n-type layers. These amorphous silicon based layers of film 5 may be of hydrogenated amorphous silicon in certain instances, but may also be of or include hydrogenated amorphous silicon carbon or hydrogenated amorphous silicon germanium, or other suitable material(s) in certain example embodiments of this invention. It is possible for the active region 5 to be of a double-junction type in alternative embodiments of this invention.

Back contact or electrode 7 may be of any suitable electrically conductive material. For example and without limitation, the back contact or electrode 7 may be of a TCO and/or a metal in certain instances. Example TCO materials for use as back contact or electrode 7 include indium zinc oxide, indium-tin-oxide (ITO), tin oxide, and/or zinc oxide which may be doped with aluminum (which may or may not be doped with silver). The TCO of the back contact 7 may be of the single layer type or a multi-layer type in different instances. Moreover, the back contact 7 may include both a TCO portion and a metal portion in certain instances. For example, in an example multi-layer embodiment, the TCO portion of the back contact 7 may include a layer of a material such as indium zinc oxide (which may or may not be doped with silver), indium-tin-oxide (ITO), tin oxide, and/or zinc oxide closest to the active region 5, and the back contact may include another conductive and possibly reflective layer of a material such as silver, molybdenum, platinum, steel, iron, niobium, titanium, chromium, bismuth, antimony, or aluminum further from the active region 5 and closer to the superstrate 11. The metal portion may be closer to superstrate 11 compared to the TCO portion of the back contact 7.

The photovoltaic module may be encapsulated or partially covered with an encapsulating material such as encapsulant 9 in certain example embodiments. An example encapsulant or adhesive for layer 9 is EVA. However, other materials such as Tedlar type plastic, Nuvasil type plastic, Tefzel type plastic or the like may instead be used for layer 9 in different instances.

TCO materials typically used as front contacts in thin-film photovoltaic devices (e.g., solar cells) are often n-type, and thus create a Schottky barrier at the interface between the TCO and the uppermost semiconductor portion of the device which may be a p-type a-Si:H portion/layer (such a Schottky barrier may be in a reverse direction to the built-in field). This barrier is problematic in that it can form a barrier for holes extracted from the cell by the front contact thereby leading to inefficient performance of the device. In order to overcome this problem, a material with a higher work function is used.

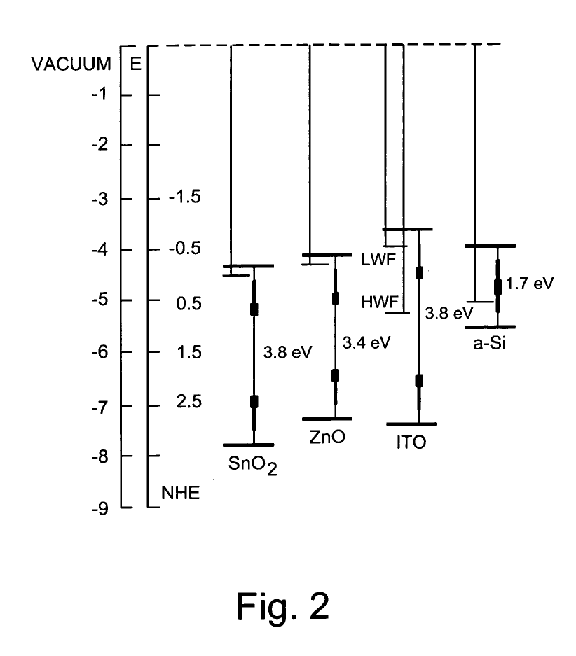

FIG. 2 summarizes the band and Fermi level positions of common TCO materials and p-type a-Si:H with respect to vacuum level and a normal hydrogen electrode (NHE). Al doped zinc oxide (ZnO:Al) has been considered as a TCO for a single film front contact for a-Si:H solar cells due to its low cost, high conductivity and high degree of transparency. However, there may be a reduced fill factor of solar cells with single layer front contacts of Al-doped zinc oxide due to the formation of rectifying contact between p-type a-Si:H and n-type Al-doped zinc oxide. Also, high recombination losses compared to fluorine-doped tin oxide may be present in cells with single layers of Al-doped zinc oxide for front contacts due to the formation of SiO₂ in the transition region. Moreover, the work function of ZnO:Al is lower than that of SnO₂:F, resulting in a higher barrier for holes at the interface between the ZnO:Al and the a-Si:H, and a wider depletion region in the a-Si:H film.

Referring to FIG. 2, the work function of indium tin oxide (ITO) depends on deposition conditions and surface preparation and varies from about 4 to 5.3 eV. When deposited using a ceramic ITO target in a pure Ar gas atmosphere, ITO films have a small work function of about 4.0 to 4.4 eV, representing a high position of the Fermi level. Such layers exhibit a high density of surface states. However, excess oxygen in an ITO film causes charge compensation due to the formation of neutral [2Sn_{In}Oᵢ] complexes, which results in a lowered position of the Fermi level and thus higher work-function values of up to about 5.3 eV or so, or higher. However, the conductivity of ITO decreases with increased oxygen content, and thus may not be suitable for a single-layer front contact (it also may not be suitable for a single-layer front contact due to its smooth surface which may trap less light and its high cost). Thus, it will be appreciated that deposition of ITO in an oxygen-rich manner is advantageous in that a high work function can result and the same may be used for high work function layer 3b in the FIG. 1 photovoltaic device.

In certain embodiments of this invention, multi-layer front contact 3 is provided by forming a thin oxygen-rich ITO layer 3b on substrate 1 over and contacting the bulk high conductivity TCO layer 3a (of or including zinc oxide, tin oxide, or the like) so as to provide for approximate or more substantial work-function matching between the front high-conductivity n-type transparent contact 3a and the uppermost portion of semiconductor film 5 which may be a p-type a-Si:H absorber layer or the like.

In certain example embodiments, the oxygen level gradually increases from the TCO/ITO interface (interface between layers 3a and 3b) to the ITO/a-Si interface (interface between layers 3b and 5). In other words, the high work function layer 3b may be oxidation graded so as to having a higher oxygen content in a portion thereof immediately adjacent semiconductor film 5 than at a portion thereof adjacent TCO 3a; this may help improve performance for the reasons discussed herein.

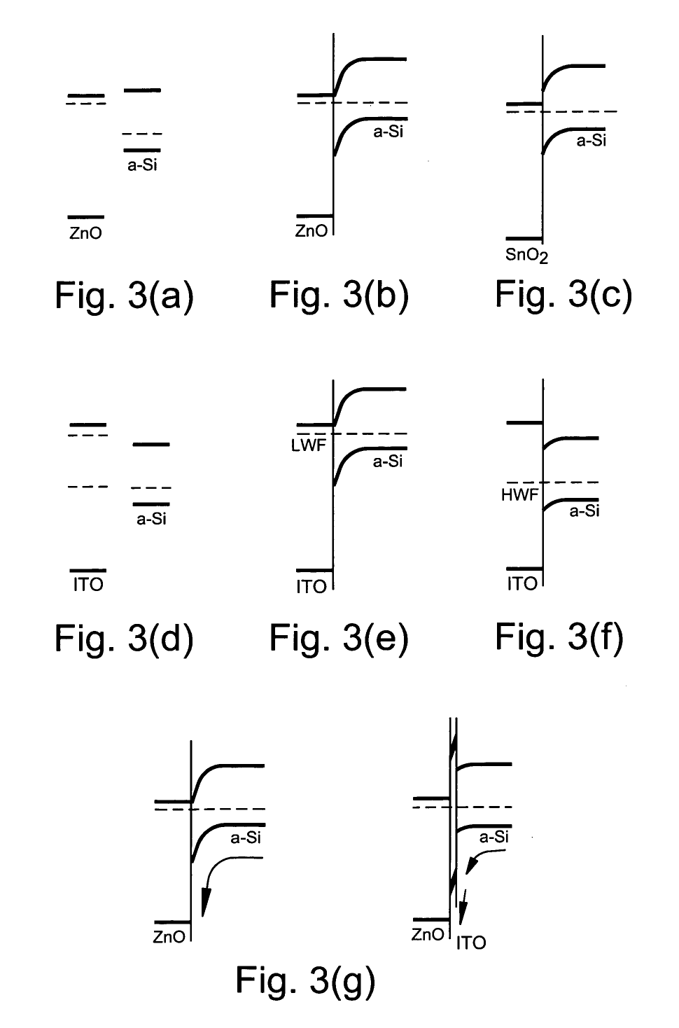

FIG. 3 is used to illustrate advantages associated with this concept.

FIG. 3(a) illustrates the relative positions of separated ZnO and a-Si:H layers; the Fermi level of the a-Si:H is lower than that of the ZnO. When the two materials are brought into contact, as in conventional solar cells, their Fermi levels substantially align thereby resulting in a high degree of bending of the conduction and valence bands as shown in FIG. 3(b). FIG. 3(c) illustrates that a smaller degree of band bending occurs in the case of an interface between a-Si:H and tin oxide, thereby showing that such an interface results in slightly better performance when tin oxide is used as a single layer front contact. FIGS. 3(d) and 3(e) demonstrate significant band bending at the contact of p-type a-Si:H and a low work-function ITO, which is disadvantageous in that it results in the formation of an inverted Schottky junction at this interface which can reduce device efficiency and/or performance. Thus, it will be appreciated from FIGS. 3(a)-3(e) that high degrees of band bending are not desirable in that device performance can be reduced.

However, as shown in FIG. 3(f), when a high work-function type of ITO is used, the Fermi level alignment at the interface does not result in a significant upward move of the conduction and valence bands of the p-type a-Si:H. Depending on the value of work function, the bands may stay flat, bend slightly upward, or bend only slightly as shown in FIG. 3(f), thereby facilitating efficient hole extraction from the photovoltaic device.

To demonstrate the advantage of certain example embodiments of this invention, FIG. 3(g) illustrates a comparison between (i) a-Si:H on ZnO as in the prior art without use of the high work-function layer (see left side of FIG. 3(g)), versus a-Si:H on ZnO with the high work-function layer 3b therebetween according to certain embodiments of this invention (see right side of FIG. 3(g)). It can be seen that the provision of the high work-function layer 3b (e.g., thin layer of oxygen-rich ITO) between the zinc oxide TCO 3a and the a-Si:H film 5 is advantageous in that there is no significant upward move of the conduction and valence bands of the a-Si:H (see right side of FIG. 3(g)), thereby resulting in improved hole extraction. Thus, the work-function matching layer 3b reduces band bending at the TCO/a-Si interface, thereby reducing the potential barrier and enhancing device performance. Moreover, standard enthalpy of formation for the ITO is around −900 kJ/mol, which is considerably higher than that for ZnO (around 348 kJ/mol) and SnO₂ (around −577.6 kJ/mol), thereby reducing ion exchange between the TCO and a-Si:H layers, which may explain why less oxidation occurs at the a-Si interface and improved performance results.

While oxygen-rich ITO is used for the high work function layer 3b in certain example embodiments of this invention, this invention is not so limited and other materials may instead be used for the high work-function TCO layer 3b in certain instances. Moreover, it is also possible that high work-function layer 3b may include multiple layers in certain example embodiments of this invention.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

1. A photovoltaic device comprising:
a front glass substrate;
an active semiconductor film;
an electrically conductive and substantially transparent front contact located between at least the front glass substrate and the semiconductor film;
wherein the front contact comprises (a) a first transparent conductive oxide (TCO) film having a relatively low work-function and (b) a second TCO film having a relatively high work-function; and
wherein the second TCO film having the relatively high work-function which is higher than the work-function of the first TCO film being located between and contacting the first TCO film and an uppermost portion of the semiconductor film.

2. The photovoltaic device of claim 1, wherein the second TCO film having the relatively high work function comprises oxygen-rich indium-tin-oxide (ITO).

3. The photovoltaic device of claim 1, wherein the first TCO film has a work-function of no greater than about 4.4 eV, and the second TCO film has a work-function of at least 4.5 eV.

4. The photovoltaic device of claim 1, wherein the second TCO film having the relatively high work-function has a work-function of from about 4.5 to 5.7 eV.

5. The photovoltaic device of claim 1, wherein the second TCO film having the relatively high work-function has a work-function of from about 4.7 to 5.3 eV.

6. The photovoltaic device of claim 1, wherein the first TCO film having the relatively low work-function comprises one or more of tin oxide and zinc oxide.

7. The photovoltaic device of claim 1, further comprising a back electrode, wherein the active semiconductor film is provided between at least the front electrode and the back electrode.

8. The photovoltaic device of claim 1, wherein the second TCO film having the relatively high work-function is from about 10-100 Å thick.

9. The photovoltaic device of claim 1, wherein the second TCO film having the relatively high work-function is oxidation graded, continuously or discontinuously, so as to have a higher oxygen content adjacent the semiconductor film than adjacent the first TCO film.

10. A front contact adapted for use in a photovoltaic device including an active semiconductor film, the front contact comprising:
a front glass substrate;
a first substantially transparent conductive oxide (TCO) film;
a second substantially transparent conductive oxide (TCO) film having a high work-function, wherein the work-function of the second TCO film is higher than that of the first TCO film; and
wherein the first TCO film is located between the glass substrate and the second TCO film, so that the second TCO film having the high work-function is adapted to be located between and contacting the first TCO film and an uppermost portion of the semiconductor film of the photovoltaic device.

11. The front contact of claim 10, wherein the second TCO film comprises oxygen-rich indium-tin-oxide (ITO).

12. The front contact of claim 10, wherein the first TCO film has a work-function of no greater than 4.4 eV, and the second TCO film has a work-function of at least 4.5 eV.

13. The front contact of claim 10, wherein the second TCO film has a work-function of from about 4.5 to 5.7 eV.

14. The front contact of claim 10, wherein the second TCO film has a work-function of from about 4.7 to 5.3 eV.

15. The front contact of claim 10, wherein the first TCO film comprises one or more of tin oxide and zinc oxide.

16. The front contact of claim 10, wherein the second TCO film is from about 10-100 Å thick.

17. The front contact of claim 10, wherein the second TCO film having the high work-function is oxidation graded, continuously or discontinuously, so as to have a higher oxygen content at a first side thereof adapted to be positioned adjacent the semiconductor film, than adjacent the first TCO film.

18. A method of making a photovoltaic device, the method comprising:
providing a glass substrate;
depositing a first substantially transparent conductive oxide (TCO) film on the glass substrate;
depositing a second substantially transparent conductive oxide (TCO) film having a relatively high work-function on the glass substrate over and contacting the first TCO film, wherein the second TCO film has a higher work-function than does the first TCO film; and
forming the photovoltaic device so that the second TCO film having the relatively high work-function is sandwiched between and contacts each of the first TCO film and a semiconductor film of the photovoltaic device.

19. The method of claim 18, wherein the second TCO film comprises oxygen-rich indium-tin-oxide (ITO).

20. The method of claim 18, wherein the first TCO film has a work-function of no greater than 4.4 eV, and the second TCO film has a work-function of at least 4.5 eV.

21. The method of claim 18, wherein the second TCO film has a work-function of from about 4.5 to 5.7 eV.

22. The method of claim 18, wherein each of said depositing steps comprises sputtering.
